(19) United States
(12) Patent Application Publication
(10) Pub. No.: US 2025/0224667 A1
(43) Pub. Date: Jul. 10, 2025

(54) APPARATUS AND METHOD FOR A LITHOGRAPHIC APPARATUS

(71) Applicant: ASML NETHERLANDS B.V., Veldhoven (NL)

(72) Inventors: Andrey NIKIPELOV, Eindhoven (NL); Ties Wouter VAN DER WOORD, Eindhoven (NL); Paul Alexander VERMEULEN, Eindhoven (NL); Zomer Silvester HOUWELING, Utrecht (NL)

(73) Assignee: ASML NETHERLANDS B.V., Veldhoven (NL)

(21) Appl. No.: 18/703,434

(22) PCT Filed: Nov. 3, 2022
(86) PCT No.: PCT/EP2022/080627

§ 371 Date: Apr. 22, 2024

(30) Foreign Application Priority Data
Nov. 25, 2021 (EP) 21210412.9

(51) Int. Cl. G03F 1/62; G03F 7/00; H01J 37/302; H01J 37/317

(52) U.S. Cl. CPC G03F 1/62; G03F 7/70958; G03F 7/70983; H01J 37/3023; H01J 37/3174

(57) ABSTRACT

An apparatus for adjusting the transmissivity of a pellicle membrane, the apparatus including an etching unit configured to etch material from the pellicle membrane, and a controller configured to control the etching unit to etch the pellicle membrane based on a predicted and/or observed wear pattern of the pellicle membrane. Also a method of adjusting the transmissivity of a pellicle membrane as well as a pellicle membrane, a pellicle assembly, and the use of the same.

### CROSS-REFERENCE TO RELATED APPLICATIONS

This application claims priority of EP application 21210412.9 which was filed on Nov. 25, 2021 and which is incorporated herein in its entirety by reference.

### FIELD

The present invention relates to an apparatus for adjusting the transmissivity of a pellicle membrane for a lithographic apparatus, particularly but not exclusively a carbon nanotube-based pellicle membrane, a method of adjusting the transmissivity of a pellicle membrane, a pellicle membrane for use in a lithographic apparatus, a pellicle assembly for a lithographic apparatus, and a use of a pellicle membrane in a lithographic apparatus or method.

### BACKGROUND

A lithographic apparatus is a machine constructed to apply a desired pattern onto a substrate. A lithographic apparatus can be used, for example, in the manufacture of integrated circuits (ICs). A lithographic apparatus may for example project a pattern from a patterning device (e.g. a mask) onto a layer of radiation-sensitive material (resist) provided on a substrate.

The wavelength of radiation used by a lithographic apparatus to project a pattern onto a substrate determines the minimum size of features which can be formed on that substrate. A lithographic apparatus which uses EUV radiation, being electromagnetic radiation having a wavelength within the range 4-20 nm, may be used to form smaller features on a substrate than a conventional lithographic apparatus (which may for example use electromagnetic radiation with a wavelength of 193 nm).

A lithographic apparatus includes a patterning device (e.g. a mask or reticle). Radiation is provided through or reflected off the patterning device to form an image on a substrate. A membrane assembly, also referred to as a pellicle, may be provided to protect the patterning device from airborne particles and other forms of contamination. Contamination on the surface of the patterning device can cause manufacturing defects on the substrate.

Pellicles may also be provided for protecting optical components other than patterning devices. Pellicles may also be used to provide a passage for lithographic radiation between regions of the lithography apparatus which are sealed from one another. Pellicles may also be used as filters, such as spectral purity filters or as part of a dynamic gas lock of a lithographic apparatus.

A mask assembly may include the pellicle which protects a patterning device (e.g. a mask) from particle contamination. The pellicle may be supported by a pellicle frame, forming a pellicle assembly. The pellicle may be attached to the frame, for example, by gluing or otherwise attaching a pellicle border region to the frame. The frame may be permanently or releasably attached to a patterning device.

Due to the presence of the pellicle in the optical path of the EUV radiation beam, it is necessary for the pellicle to have high EUV transmissivity. A high EUV transmissivity allows a greater proportion of the incident radiation through the pellicle. In addition, reducing the amount of EUV radiation absorbed by the pellicle may decrease the operating temperature of the pellicle. Since transmissivity is at least partially dependent on the thickness of the pellicle, it is desirable to provide a pellicle which is as thin as possible whilst remaining reliably strong enough to withstand the sometimes hostile environment within a lithography apparatus.

It is therefore desirable to provide a pellicle which is able to withstand the harsh environment of a lithographic apparatus, in particular an EUV lithography apparatus. It is particularly desirable to provide a pellicle which is able to withstand higher powers than previously.

It is also desirable to increase the operational lifespan of the pellicle membrane in order to reduce the frequency with which the pellicle membrane is replaced and to thereby minimise downtime of the lithographic apparatus. In use, pellicles degrade due to effects of the scanner environment (temperature, hydrogen plasma, energetic photons absorbed). The degradation is not uniform in the plane of the pellicle and translates into distortion of transmission uniformity and so, negatively affects imaging. This can be mitigated by a (periodic) correction of the transmission.

Whilst the present application generally refers to pellicles in the context of lithography apparatus, in particular EUV lithography apparatus, the invention is not limited to only pellicles and lithography apparatus and it is appreciated that the subject matter of the present invention may be used in any other suitable apparatus or circumstances.

The present invention has been devised in an attempt to address at least some of the problems identified above.

### SUMMARY OF THE INVENTION

According to a first aspect of the present invention, there is provided an apparatus for adjusting the transmissivity of a pellicle membrane, said apparatus including an etching unit configured to etch material from the pellicle membrane, and a controller, wherein the controller is configured to control the etching unit to etch the pellicle membrane based on a predicted and/or observed wear pattern of the pellicle membrane. Preferably, the pellicle membrane is a carbon nanotube-based pellicle membrane.

In operation, a pellicle membrane is located to protect a reticle from contaminants. Electromagnetic radiation, such as EUV radiation, passes through the pellicle membrane and interacts with the reticle to pattern the electromagnetic radiation. The patterned electromagnetic radiation then passes back through the pellicle membrane, after which the patterned electromagnetic radiation is used to expose resist on a wafer. The environment around the pellicle and the reticle contains hydrogen. The hydrogen can be converted into a plasma by the electromagnetic radiation. Material from the pellicle membrane can be removed by exposure to the hydrogen plasma, as well as by other routes. Since the environment of the pellicle membrane is not uniform across the membrane, the rate at which material is removed from the pellicle membrane is not uniform. Pellicle membranes require both mechanical stability and optical stability. Whilst the mechanical stability of pellicle membranes comprising carbon nanotubes does decrease as material is removed, this is a relatively slow process. For example carbon nanotube (CNT) pellicle membranes are at risk of mechanical failure after carbon removal corresponding to single pass transmission change of from 96% to 98%. On the other hand, if optical non-uniformity exceeds 0.2%, the pellicle membrane is considered as being out of specification. Previously, the pellicle membrane would be exchanged for a new pellicle membrane. However, this replacement takes time and the throughput of the apparatus is reduced due to the downtime required to replace the pellicle membrane. The present invention provides for an apparatus which is configured to etch the pellicle membrane based on a predicted and/or observed wear pattern of the pellicle membrane. The wear pattern, namely the areas of the pellicle membrane from which material is removed, is affected by many factors, although it is possible to predict how a pellicle membrane will wear in use. It is therefore possible to etch the pellicle membrane based on such a predicted wear pattern. Alternatively or additionally, the wear pattern of the pellicle membrane can be observed after a period of use and then the pellicle membrane can be etched by the apparatus according to the present invention to account for the wear of the pellicle membrane. In this way, the optical non-uniformity of the pellicle membrane can be controlled, without the need to replace the pellicle membrane. It will be appreciated that pellicle based on materials other than carbon nanotubes may also suffer from transmission non-uniformity drift and can also be corrected according to the present invention.

The apparatus may be configured to etch material from the pellicle membrane in an array of pixels. Due to diffraction orders which diverge from the typical pattern into 0.3-0.5 Numerical Aperture (NA) at the reticle and the distance between pellicle and reticle of few mm, small non-uniformities in the pellicle membrane transmission, such as 0.5% or less, which are smaller than around 0.3-0.5 mm are averaged out at the reticle and at the aerial image wafer. As such, it is not necessary to correct the transmission of the pellicle membrane to a higher resolution (than said 0.3-0.5 mm). Therefore, the apparatus can be configured to etch the material in an array of pixels, with resolution at least 0.3-0.5 mm, 0.3-1 mm, or coarser, depending on the gradient of transmission non-uniformity, introduced by the EUV scanner environment).

The pixels may have an edge length of from around 0.1 mm to around 1 mm, from around 0.3 mm to around 1 mm,, from around 0.2 mm to around 0.6 mm, from around 0.3 mm to around 0.5 mm, or greater than 0.5 mm. As such, the edge length may be around 0.1 mm, around 0.2 mm, around 0.3 mm, around 0.4 mm, around 0.5 mm, around 0.6 mm, around 0.7 mm, around 0.8 mm, around 0.9 mm or around 1.0 mm. As mentioned, the non-uniformity is averaged out and so the pixel size can be selected depending on the requirement for how accurately the non-uniformity needs to be controlled. In areas which are less sensitive to non-uniformity, the pixels can be larger, whereas in areas which are more sensitive to non-uniformity, the pixels can be smaller. Some pellicle areas can cover the reticle areas that are pattern-free and so have relaxed specifications for the transmission uniformity, such areas can be excluded from the pixelated partial etch of the pellicle completely.

The apparatus may be configured to operate within a lithographic apparatus. A lithographic apparatus requires a highly controlled internal environment that is free from contamination. It is therefore desirable to avoid moving elements (including pelliclized reticle) into and out of the apparatus if it can be avoided since there is a risk of contamination when doing so. By configuring the apparatus of the present invention to operate within a lithographic apparatus, the chance of introducing additional contamination is reduced. The apparatus may be included in a scanner, or may be separate from the scanner.

The apparatus may be configured to etch the pellicle membrane whilst the pellicle membrane is still attached to a pellicle support frame and reticle. Pellicle membranes can be glued to a support frame to provide them with additional mechanical strength and stability. When pellicle membranes are separated from the support frame, there is a risk of damage to the pellicle membrane as well as a risk of the generation of contaminant particles. With a pellicle mounted onto the reticle for the duration of the partial pixelated etch of the pellicle membrane, there is no risk of reticle contamination with critical particles (the pellicle protects reticle even for the duration of this treatment).

The apparatus may be configured to etch the pellicle membrane to within a uniformity of around 0.2% or less, around 0.15% or less, around 0.1% or less, around 0.05% of less, or substantially 0%, at least over the reticle area that contains pattern that is sensitive to such a transmission.

The controller may be configured to over-etch the pellicle membrane based on the predicted and/or observed wear pattern to compensate for the wear pattern in use. During use, the pellicle membrane will wear at different rates and so the non-uniformity of the membrane will change. Some areas will wear at a higher rate than others and so the transmissivity of these different areas will change over time at different rates. The rate of etching or wear of a particular area of the pellicle membrane is effected by, inter alia, reticle local pattern reflectivity, cooling or heating anisotropy, and plasma concentration. In embodiments, the apparatus may be configured to etch the pellicle membrane such that it is has a substantially uniform transmissivity. Alternatively, the apparatus may be configured to over-etch the areas of the pellicle membrane which are subject to less wear. In this way, during use, the transmissivity of such areas changes less than the transmissivity of areas which are subject to higher wear. Over time, the transmissivity of the areas which are subject to greater wear will “catch up” with the areas subject to less wear. Over further use, the areas which are subject to greater wear will continue to wear until the non-uniformity between the different areas becomes out of specification. For example, the apparatus may be configured to over-etch the areas subject to less wear such that there is a non-uniformity between such areas and higher wear areas of, for example, 0.2%. Over time, the non-uniformity will reduce towards 0% and then continue to −0.2% (with the minus sign indicting that the non-uniformity has reversed from the higher wear areas being less transmissive by 0.2% to being more transmissive by 0.2%). In this way, the pellicle membrane can remain within specification for twice as long as would be the case where the pellicle membrane was etched to be have a substantially uniform transmissivity. It will be appreciated that it is the transmissivity of the so-called quality area which is important and the transmissivity uniformity relates to the difference in uniformity in respect of the quality area as opposed to the entirety of the membrane.

The etching unit may include any suitable etching means. The etching unit may include a focused electron beam etcher, with an optional gas source. The optional gas source may be configured to provide a reducing gas, such as H₂, or gas mixture. The etching unit may include a DC-driven array of electron emitters and/or H₂⁻ and H⁻ generators. The etching unit may include an AC-powered dielectric barrier discharge unit. The etching unit may include a hydrogen radical generator. The hydrogen radical generator may be configured to provide uniform flux to the pellicle membrane. The etching unit may include a mechanism to ground or bias the pellicle.

The etching unit may be configured to introduce plasma. The plasma may be low power, such as around 10 W or less. The plasma may be introduced in addition to the hydrogen radical flux and/or hydrogen ion flux in order to more rapidly etch the carbon from the membrane.

The gas mixture may include at least one noble gas. The gas or gas mixture may include hydrogen. The pressure of the gas or gas mixture may be less than around 100 Pa, preferably less than around 10 Pa, preferably less than around 1 Pa. The pressure of the gas or gas mixture may be from around 0.01 to around 1 Pa.

These etching means are selective to carbon and do not perturb the reticle. As such, it is possible to operate these etching means in situ without the need to remove the pellicle. This reduces downtime of the lithographic apparatus. These also allow the etching to be completed in 100 seconds or less and do not require long thermalization. In addition, by being able to adjust the transmissivity of the pellicle rapidly, it obviates the need to have a second reticle in order to keep production going.

According to a second aspect of the present invention, there is provided a method of adjusting the transmissivity of a pellicle membrane, the method including the step of etching material from the pellicle membrane in a pattern based on a predicted and/or observed wear pattern of the pellicle membrane. The wear pattern is dependent on the scanner/illuminator setting, EUV source power, EUV dose to image, and reticle pattern or average reflectivity. Preferably, the pellicle membrane is a carbon-nanotube based pellicle membrane.

As with the first aspect of the present invention, the method of the present invention provides for selective etching of the pellicle membrane to take account of how the pellicle membrane will be etched in use in a lithographic apparatus. Previously, the etching of a pellicle membrane was independent of the predicted and/or observed wear pattern of the pellicle membrane. The method may include a step of determining the wear pattern of a pellicle membrane and/or predicting the wear pattern of a pellicle membrane.

The method may include etching the pellicle membrane until the transmissivity of the quality area of the pellicle membrane is within a uniformity of around 0.2% or less, around 0.15% or less, around 0.1% or less, or around 0.05% or less.

By etching the transmissivity of the quality area of the pellicle membrane such that it is uniform to around 0.2% or less, the pellicle membrane can be within specification.

The method may include etching a pattern into the pellicle membrane which is the inverse of the predicted and/or observed wear pattern.

In operation, the pellicle membrane will wear or be etched at different rates over its surface. This will produce a wear pattern. The wear pattern may be predicted based on modelling or prior observations. The wear pattern may be observed after a given period of time. Over time, the areas which are subject to the highest wear will have a different transmissivity than other areas subject to less wear. This will increase the non-uniformity of the pellicle membrane, particularly the quality area, until a point where the difference in transmissivity results in the non-uniformity of the pellicle membrane exceeding the specification limits. In either case, the corrective etching of the pellicle membrane can then be undertaken based on the wear pattern to correct this non-uniformity and bring the pellicle membrane back into specification. By etching the inverse pattern, the transmissivity of the pellicle membrane can be corrected.

The method may further include over-etching the pellicle membrane in a pattern inverse of the predicted and/or observed wear pattern.

As described, after use, the transmissivity of different parts of the quality area of the pellicle membrane will have changed relative to one another. Under the same conditions, the wear pattern will be consistent, so it is possible to over-etch certain portions of the pellicle membrane. As such, the areas which are subject to less wear in use can be etched such that they are relatively more transmissive than the areas which are subject to more wear in use. In this way, in use, the areas subject to the highest wear will wear faster than the other areas and so the transmissivity of the high wear areas will catch up with that of the low wear areas. In continued operation, the high wear areas will wear more until the non-uniformity necessitates that the pellicle membrane be replaced or refurbished. By over-etching certain parts of the pellicle membrane, the operational lifetime of the pellicle membrane can effectively be doubled.

The method may include etching the pellicle membrane within a lithographic apparatus, optionally within a reticle exchange device or a reticle library.

It is highly desirable for lithographic apparatuses to be as free as possible from contamination, which may be in the form of particles. As such, by conducting the method of the present invention within the lithographic apparatus, the risk of contamination is reduced since the apparatus can remain a sealed system and there is less risk of contaminants inadvertently being introduced into the apparatus.

The method may include etching the pellicle membrane whilst the pellicle membrane is still attached to a pellicle support frame and reticle.

Since pellicle membranes are very thin, they are often supported by a more robust pellicle support frame. Pellicle membranes can be glued to the pellicle support frame and so if they are detached, there is a risk of damage to the pellicle membrane itself, but also a risk of the generation of particles, which can lead to contamination of the pellicle membrane or the wider lithographic apparatus. The method may include etching the pellicle membrane in a series of pixels, optionally wherein the pixels have an edge length of from around 0.1 mm to around 1.0 mm, optionally from around 0.2 mm to around 0.7 mm, or optionally from around 0.3 mm to around 0.5 mm, optionally around 0.3 mm, optionally around 0.5 mm to 1 mm, optionally 1 mm or greater.

As described in respect of the first aspect of the present invention, it is possible to partially etch the pellicle membrane as a series of pixels rather than continuously over the surface since non-uniformities smaller than around 0.3 mm, 0.5 mm or 1 mm are averaged out at the reticle or at wafer. This allows the etching process to be conducted more quickly than would otherwise be the case. It will be appreciated that in certain areas, the pixels may be smaller and that in other areas the pixels used may be larger.

The method may include rasterization of the etching electron beam over the surface of the pellicle membrane to generate the etching pattern. The etching pattern will take into account the observed and/or predicted wear pattern of the pellicle membrane.

The method may include etching via a focused electron beam etcher and an optional gas source, optionally wherein the gas source is a reducing gas or gas mixture, or via a DC-driven array of electron emitters or H₂⁻ or H⁻ generators, or via an AC-powered dielectric barrier discharge unit, arranged into a one-dimensional or two-dimensional array, typically the size of the units in the DC or AC plasma etchers is smaller or equal to the required size of partial etch pixels.

Any selective etching method may be utilised. Preferably the etching method is selective towards carbon and does not etch the materials of the reticle, such as Ru, Ta, Cr.

The etching step may take place in an atmosphere at a pressure of less than 100 Pa, preferably from about 0.01 to about 1 Pa.

The etching may take place in a reducing atmosphere, optionally a hydrogen containing atmosphere.

The method may include the step of introducing a plasma. Plasma has the ability to etch carbon nanotube based pellicle membranes. The method may include the step of introducing atomic hydrogen, for example by hydrogen radical generators (hot filaments), the radicals have the ability to accelerate etching of CNTs by an electron beam.

The method may further include grounding or electrically biasing the pellicle membrane. This allows the energy of ions and/or electrons hitting the surface to be controlled that changes the etch yield, this also allow to prevent undesired charging of the pellicle (and/or reticle) by the current of the incident electron beam.

The method may include moving an etching unit and the pellicle membrane relative to one another. The etching unit does not need to be so large as to be able to etch the entirety of the pellicle membrane at once and so the unit and the pellicle membrane can be moved relative to one another to allow the etching unit to etch the surface of the pellicle membrane.

The method may include scanning an electron beam over the pellicle membrane to effect etching. As such, additionally or alternatively to moving the etching unit and/or pellicle membrane, the location of etching can be controlled by directing an electron beam.

The current of the electron beam may be from about 0.01 mA to about 100 mA, preferably from about 0.1 to about 10 mA.

The electron beam may have a modulation of from around 10% to around 90% in under 200 μs, preferably under 100 μs.

The electron beam energy may be from around 30 eV to around 3 keV, preferably from around 100 eV to around 300 eV.

The electron beam spot diameter at the pellicle membrane may be around 1 mm or less, preferably around 0.3 mm or less. Generally, the electron beam spot diameter should be equal or less then the size of the required partial etch pixel.

According to a third aspect of the present invention, there is provided a carbon nanotube based pellicle membrane for use in a lithographic apparatus, said pellicle membrane comprising an etch pattern which is the inverse of a predicted and/or observed wear pattern in use.

As described in relation to the first and second aspects of the present invention, by providing a pellicle membrane which is etched in a pattern inverse of a predicted and/or observed wear pattern in use, it is possible to effectively double the operational lifetime of a pellicle before it becomes out of specification and needs replacement or refurbishing.

According to a fourth aspect of the present invention, there is provided a pellicle assembly including a pellicle membrane according to the third aspect of the present invention.

According to a fifth aspect of the present invention, there is provided the use of the apparatus, method, pellicle membrane, or pellicle assembly according to any aspect of the present invention in a lithographic apparatus or method.

It will be appreciated that features described in respect of one embodiment may be combined with any features described in respect of another embodiment and all such combinations are expressly considered and disclosed herein.

### BRIEF DESCRIPTION OF THE DRAWINGS

Embodiments of the invention will now be described, by way of example only, with reference to the accompanying schematic drawing in which corresponding reference symbols indicate corresponding parts, and in which:

FIG. 1 depicts a lithographic apparatus according to an embodiment of the invention;

FIG. 2 depicts a reticle, a pristine CNT pellicle and a CNT pellicle which has been used in a lithographic apparatus;

FIG. 3 depicts schematic representations of the printed image of a reticle protected by a pristine pellicle and a reticle protected by a used pellicle;

FIG. 4 depicts an exemplary etching pattern complementary to a wear pattern to result in a homogenised CNT pellicle transmission;

FIG. 5 depicts an exemplary etching pattern complementary to a wear pattern to result in a CNT pellicle having a pattern in which the regions of different transmissivity are etched to the transmissivity of the most transmissive region;

FIG. 6 depicts an embodiment of an etching unit according to the present invention; and

FIG. 7 depicts an embodiment of an etching unit according to the present invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements.

### DETAILED DESCRIPTION

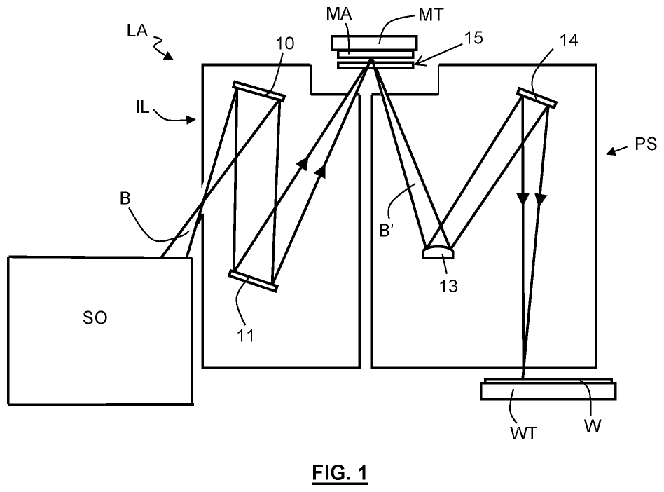

FIG. 1 shows a lithographic system including a pellicle 15 (which may also be referred to as a membrane assembly) according to the present invention. The lithographic system comprises a radiation source SO and a lithographic apparatus LA. The radiation source SO is configured to generate an extreme ultraviolet (EUV) radiation beam B. The lithographic apparatus LA comprises an illumination system IL, a support structure MT configured to support a patterning device MA (e.g. a mask), a projection system PS and a substrate table WT configured to support a substrate W. The illumination system IL is configured to condition the radiation beam B before it is incident upon the patterning device MA. The projection system is configured to project the radiation beam B (now patterned by the mask MA) onto the substrate W. The substrate W may include previously formed patterns. Where this is the case, the lithographic apparatus aligns the patterned radiation beam B with a pattern previously formed on the substrate W. In this embodiment, the pellicle 15 is depicted in the path of the radiation and protecting the patterning device MA. It will be appreciated that the pellicle 15 may be located in any required position and may be used to protect any of the mirrors in the lithographic apparatus.

The radiation source SO, illumination system IL, and projection system PS may all be constructed and arranged such that they can be isolated from the external environment. A gas at a pressure below atmospheric pressure (e.g. hydrogen) may be provided in the radiation source SO. A vacuum may be provided in illumination system IL and/or the projection system PS. A small amount of gas (e.g. hydrogen) at a pressure well below atmospheric pressure may be provided in the illumination system IL and/or the projection system PS.

The radiation source SO shown in FIG. 1 is of a type which may be referred to as a laser produced plasma (LPP) source. A laser, which may for example be a CO₂ laser, is arranged to deposit energy via a laser beam into a fuel, such as tin (Sn) which is provided from a fuel emitter. Although tin is referred to in the following description, any suitable fuel may be used. The fuel may for example be in liquid form, and may for example be a metal or alloy. The fuel emitter may comprise a nozzle configured to direct tin, e.g. in the form of droplets, along a trajectory towards a plasma formation region. The laser beam is incident upon the tin at the plasma formation region. The deposition of laser energy into the tin creates a plasma at the plasma formation region. Radiation, including EUV radiation, is emitted from the plasma during de-excitation and recombination of ions of the plasma.

The EUV radiation is collected and focused by a near normal incidence radiation collector (sometimes referred to more generally as a normal incidence radiation collector). The collector may have a multilayer structure which is arranged to reflect EUV radiation (e.g. EUV radiation having a desired wavelength such as 13.5 nm). The collector may have an elliptical configuration, having two ellipse focal points. A first focal point may be at the plasma formation region, and a second focal point may be at an intermediate focus, as discussed below.

The laser may be separated from the radiation source SO. Where this is the case, the laser beam may be passed from the laser to the radiation source SO with the aid of a beam delivery system (not shown) comprising, for example, suitable directing mirrors and/or a beam expander, and/or other optics. The laser and the radiation source SO may together be considered to be a radiation system.

Radiation that is reflected by the collector forms a radiation beam B. The radiation beam B is focused at a point to form an image of the plasma formation region, which acts as a virtual radiation source for the illumination system IL. The point at which the radiation beam B is focused may be referred to as the intermediate focus. The radiation source SO is arranged such that the intermediate focus is located at or near to an opening in an enclosing structure of the radiation source.

The radiation beam B passes from the radiation source SO into the illumination system IL, which is configured to condition the radiation beam. The illumination system IL may include a facetted field mirror device 10 and a facetted pupil mirror device 11. The faceted field mirror device 10 and faceted pupil mirror device 11 together provide the radiation beam B with a desired cross-sectional shape and a desired angular distribution. The radiation beam B passes from the illumination system IL and is incident upon the patterning device MA held by the support structure MT. The patterning device MA reflects and patterns the radiation beam B. The illumination system IL may include other mirrors or devices in addition to or instead of the faceted field mirror device 10 and faceted pupil mirror device 11.

Following reflection from the patterning device MA the patterned radiation beam B enters the projection system PS. The projection system comprises a plurality of mirrors 13, 14 which are configured to project the radiation beam B onto a substrate W held by the substrate table WT. The projection system PS may apply a reduction factor to the radiation beam, forming an image with features that are smaller than corresponding features on the patterning device MA. A reduction factor of 4 may for example be applied. Although the projection system PS has two mirrors 13, 14 in FIG. 1, the projection system may include any number of mirrors (e.g. six mirrors).

The radiation sources SO shown in FIG. 1 may include components which are not illustrated. For example, a spectral filter may be provided in the radiation source. The spectral filter may be substantially transmissive for EUV radiation but substantially blocking for other wavelengths of radiation such as infrared radiation.

In an embodiment the membrane assembly 15 is a pellicle for the patterning device MA for EUV lithography. The membrane assembly 15 of the present invention can be used for a dynamic gas lock or for a pellicle or for another purpose. In order to ensure maximized EUV transmission and minimized impact on imaging performance it is preferred that the membrane is only supported at the border.

If the patterning device MA is left unprotected, the contamination can require the patterning device MA to be cleaned or discarded. Cleaning the patterning device MA interrupts valuable manufacturing time and discarding the patterning device MA is costly. Replacing the patterning device MA also interrupts valuable manufacturing time.

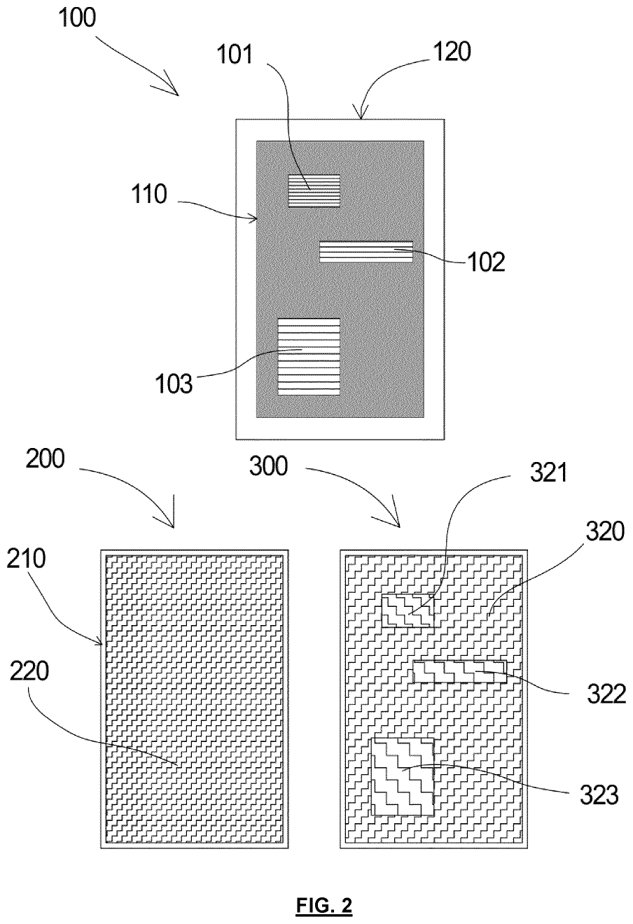

FIG. 2 depicts a reticle 100, a pristine CNT pellicle 200, and a CNT pellicle 300 which has been used in a lithographic apparatus. The reticle 100 includes an absorber 110 on the blank 120. In the depicted embodiment, the reticle 100 includes patterned regions 101, 102, 103 with different average reflectivities. Pristine CNT pellicle 200 includes a uniform CNT mesh 220 and a border or frame 210. Used CNT pellicle 300, which has been used when exposing wafers, and has therefore become more transparent to EUV radiation. The regions 321, 322, 323 above the patterned regions 101, 102, 103 lose even more carbon due to EUV plasma etching, the increased reflectivity of the underlying patterned regions 101, 102, 103, and therefore more transmissivity is gained. As such, over time in use, the once pristine pellicle with a uniform transmissivity becomes non-uniform and ultimately this will lead to the pellicle membrane to being out of specification. It will be appreciated that remedial action is undertaken before the pellicle membrane becomes out of specification, so the pellicle membrane will be replaced and/or refurbished a suitable time period before it goes out of specification.

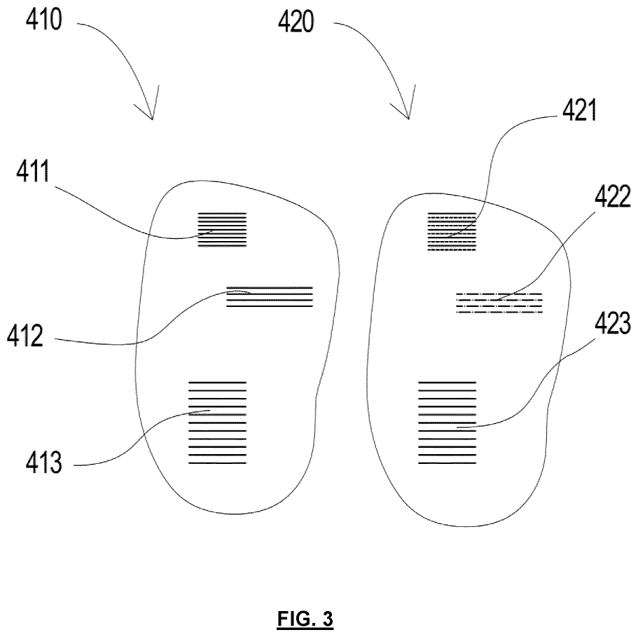

FIG. 3 depicts schematic representations of the printed image of a reticle 410 protected by a pristine pellicle and the printed image of a reticle 420 protected by a used pellicle. When the pristine pellicle is used, regions 411, 412, 413 are printed with a critical dimension which is in specification. As depicted by the broken lines, the image created by the reticle 420 protected by the used pellicle delivers sub-optimal performance and uncorrectable dose for at least some of the regions 421, 422 and optimal for only one region 423 such that only region 423 is printed with the design critical dimension. Regions 421, 422 have an out of specification critical dimension, which is proportional to the transmissivity delta.

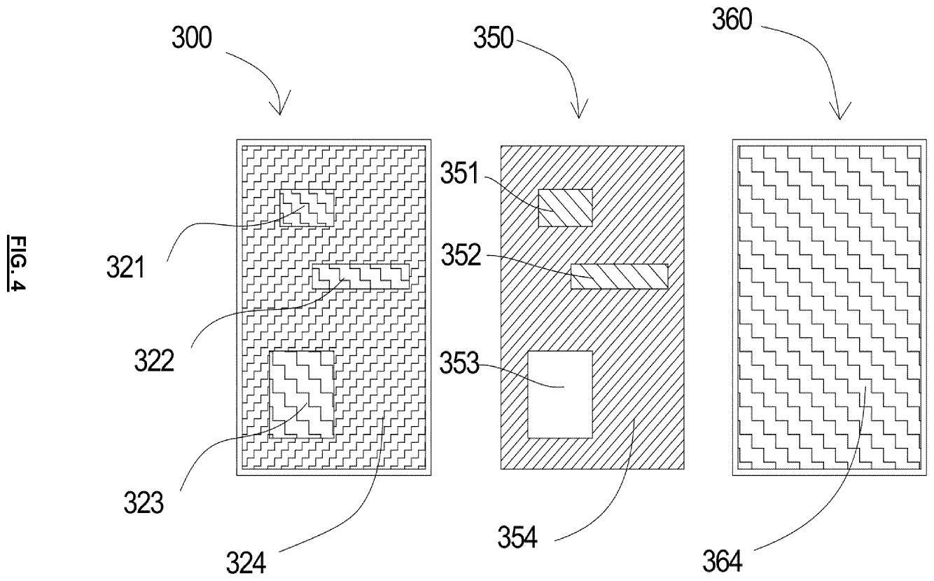

FIG. 4 depicts an exemplary etching pattern complementary to a wear pattern to result in a homogenised CNT pellicle transmission. The depiction of pellicle 300 shows the wear pattern of the pellicle, which includes regions 321, 322, 323 which have worn such that they have different transmissivities. Pattern 350 is the etch profile which is the inverse of the wear pattern of pellicle 300 and is configured such that the transmissivity of the CNT pellicle can be homogenised to provide a CNT pellicle membrane 360 with a uniform transmissivity 364. As such, the etching pattern is determined based on the observed or predicted wear pattern of the pellicle membrane.

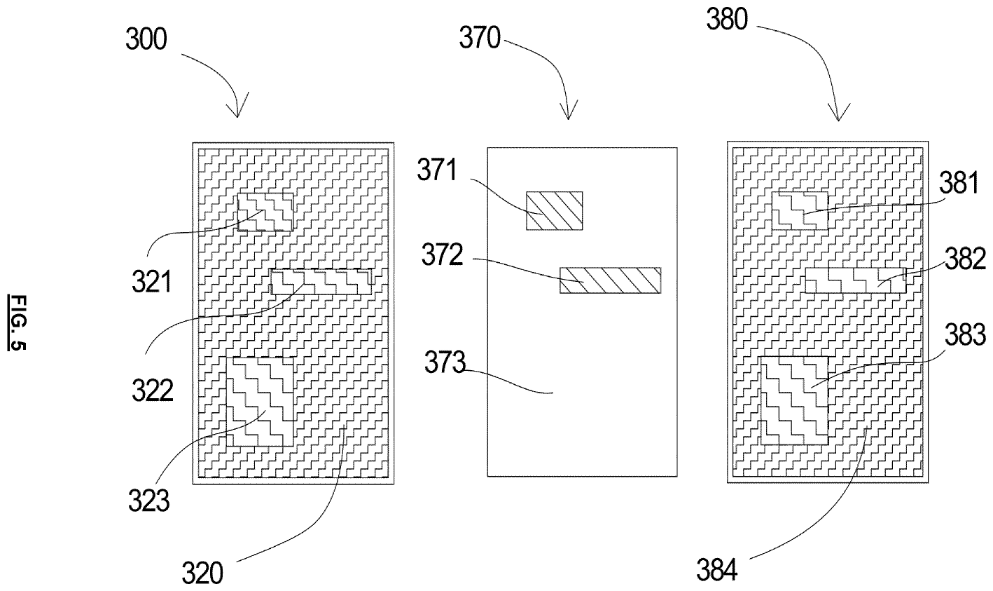

FIG. 5 depicts an alternative etching pattern which is complementary to an observed or predicted wear pattern. Unlike that depicted in FIG. 4, the wear pattern is configured to homogenise the CNT pellicle transmissivity to the level of the most transparent patch on the pellicle 323, but only for patterned regions. As such, after the pellicle has been treated, the patterned reticle regions provide homogenous transmission 381, 382, 383. As such, since region 373 is most transmissive, the other patterned regions 371, 372 may be etched to have the same transmissivity as region 373. It will be appreciated that the size, shape, number and positioning of the regions 371, 372, 373 is exemplary and will change depending on the particular reticle being protected.

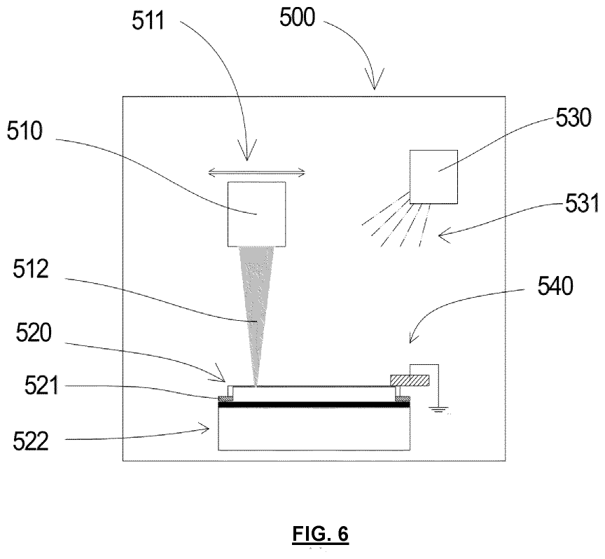

FIG. 6 depicts an embodiment of an etching unit which may be used to etch CNT pellicle membranes. The unit includes a control environment 500 containing a low pressure gas or gas mix, such as hydrogen. The gas mix may include at least one of oxygen, hydrogen, water, hydrogen peroxide, or other molecular gases comprising one or more of hydrogen, oxygen, nitrogen and carbon. The gas mix can also include a noble gas. The control environment 500 may be located within a lithographic apparatus. The control environment 500 includes the pelliclised reticle 522, 521, 520 and a source 510 of a focused electron beam 512 that is suspended on stage 511. Alternatively or additionally, the control environment 500 is provided with a system of electrodes enabling a progressive scan of the electron beam 512. The pellicle 520 may be grounded 540. Optionally, a hydrogen radical generator or a plasma source 530 provide ions and/or radicals 531 with a homogenous flux to the pellicle. The rate of etching of CNT pellicles by an electron beam is increased in the presence of either hydrogen radicals or hydrogen ions. The apparatus may include a controller (not shown) which is configured to control the etching unit to etch the CNT pellicle membrane in accordance with a predetermined pattern. This etching unit may therefore be configured to deliver pre-defined charge density at constant energy to pre-defined locations at the pellicle, such as in the form of etch pixels. The amount of carbon removed is a function of charge density.

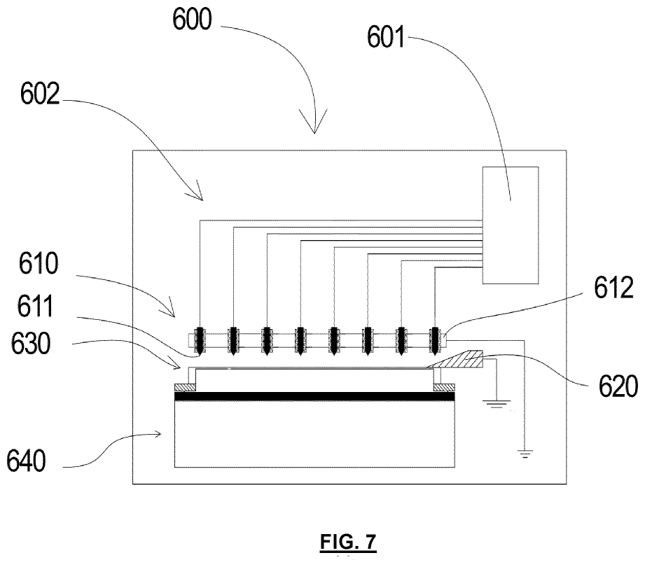

FIG. 7 depicts another embodiment of an etching unit which may be used to etch CNT pellicle membranes. The unit includes a control environment 600 containing a low pressure gas, such as hydrogen. The control environment 600 includes a pelliclised reticle 640, 630. A system 602 of individually controlled high voltage (HV) electrodes 610, 611 is provided above the pellicle. The electrodes may be separated from the surface of the pellicle by from around 0.3 to 3 mm. Each HV electrode may be partially or fully wrapped in dielectric material such that the HV electrodes have sharp, bare features pointing towards the pellicle acting as electric field concentrators. The electrodes may be provided on a common, grounded plane 612. A controller 601 may be provided and be configured to control the current, voltage, time ON or duty cycle to each individual electrode such that the resulting etch is complementary to the EUV induced etch. This may be the full pellicle or only in regions above the reflecting regions of the reticle. The electrodes may be separated by from around 0.3 mm to around 3 mm. The electrodes may operate at a voltage of from around 10 V to around 1 kV. The gas pressure may be from around 0.01 to around 100 Pa. The pellicle may be grounded 540, 620.

As such, the present invention provides for the feed back or feed forward correction of CNT pellicle transmission non-uniformity, inflicted by (non-uniform) EUV plasma environment. General benefit of the invention is the possibility to provide such a correction for a pelliclized reticle, that ensures zero contaminants are deposited on the reticle during such a treatment and extends the useful lifetime of the given pellicle.

While specific embodiments of the invention have been described above, it will be appreciated that the invention may be practiced otherwise than as described.

The descriptions above are intended to be illustrative, not limiting. Thus it will be apparent to one skilled in the art that modifications may be made to the invention as described without departing from the scope of the claims set out below.

1. An apparatus for adjusting the transmissivity of a pellicle membrane, the apparatus comprising:
an etching unit configured to etch material from the pellicle membrane, and
a controller configured to control the etching unit to etch the pellicle membrane based on a predicted and/or observed wear pattern of the pellicle membrane.

2. The apparatus according to claim 1, configured to etch material from the pellicle membrane in an array of pixels.

3. The apparatus according to claim 2, wherein the pixels have an edge length of from around 0.1 mm to around 1.0 mm

4. The apparatus according to claim 1, configured to operate within a lithographic apparatus.

5. The apparatus according to claim 1, configured to etch the pellicle membrane whilst the pellicle membrane is still attached to a pellicle support frame and reticle.

6. The apparatus according to claim 1, wherein the controller is configured to control the etching unit to etch the pellicle membrane to within a uniformity of around 0.2% or less.

7. The apparatus according to claim 1, wherein the controller is configured to control the etching unit to over-etch the pellicle membrane based on the predicted and/or observed wear pattern to compensate for the wear pattern in use.

8. The apparatus according to claim 1, wherein the etching unit is configured to provide a focused electron beam, or includes a DC-driven array of electron emitters or H₂⁻ and H⁻ generators, or includes an AC-powered dielectric barrier discharge array, and/or includes a hydrogen radical generator.

9. A method of adjusting the transmissivity of a pellicle membrane, the method including etching material from the pellicle membrane in a pattern based on a predicted and/or observed wear pattern of the pellicle membrane.

10. The method according to claim 9, wherein method includes etching the pellicle membrane until the transmissivity of the quality area of the pellicle membrane is within a uniformity of around 0.2% or less.

11. The method according to claim 9, wherein the method includes etching a pattern into the pellicle membrane which is the inverse of the predicted and/or observed wear pattern.

12. The method according to claim 9, wherein the method includes etching the pellicle membrane within a lithographic apparatus.

13. The method according to claim 9, wherein the method includes etching the pellicle membrane whilst the pellicle membrane is still attached to a pellicle support frame and reticle.

14. The method according to claim 9, wherein the method includes etching the pellicle membrane in a series of pixels.

15. The method according to claim 9, wherein the method includes rasterization of an electron beam with respect to the surface of the pellicle membrane to generate the etching pattern.

16. The method according to claim 9, wherein the method includes etching via a focused electron beam, or via a DC-driven array of electron emitters or H₂⁻ and H⁻ generators, or via an AC-powered dielectric barrier discharge unit array.

17.-18. (canceled)

19. The method according to claim 9, wherein the method further includes introducing a plasma.

20. The method according to claim 9, wherein the method further includes grounding or electrically biasing the pellicle membrane.

21.-26. (canceled)

27. A carbon nanotube based pellicle membrane for use in a lithographic apparatus, the pellicle membrane comprising an etch pattern which is the inverse of a predicted and/or observed wear pattern in use.

28. A pellicle assembly including the pellicle membrane according to claim 27.

29. (canceled)
